(19) United States
(12) Patent Application Publication
(10) Pub. No.: US 2014/0079175 A1
(43) Pub. Date: Mar. 20, 2014

(54) Shift Register Driving Apparatus And Display

(71) Applicant: BOE Technology Group Co., Ltd., Beijing (CN)

(72) Inventor: Zhongyuan Wu, Beijing (CN)

(73) Assignee: BOE Technology Group Co., Ltd., Beijing (CN)

(21) Appl. No.: 13/995,143

(22) PCT Filed: Nov. 30, 2012
(86) PCT No.: PCT/CN12/85687

§ 371 Date: Jun. 17, 2013

(30) Foreign Application Priority Data
May 21, 2012 (CN) 201210159389.5

(51) Int. Cl. H03K 3/012; G11C 27/04

(52) U.S. Cl. CPC H03K 3/012; G11C 27/04
USPC 377/72; 377/70

(57) ABSTRACT

A shift register, a driving apparatus and a display. The shift register comprises: an evaluating unit for receiving a second clock signal and outputting an output signal to a signal output terminal under a control of an input signal; a reset controlling unit, a first terminal of which being connected to the evaluating unit and receiving the input signal, a second terminal of which receiving a first clock signal, a third terminal of which receiving a low level signal, for inputting a control signal to a reset unit under controls of the input signal and the first clock signal; the reset unit for receiving a high level signal and resetting the signal output terminal under a control of the control signal input by the reset controlling unit. When the shift register evaluates the output terminal, the gate of the reset transistor (4) is charged rapidly, which renders that the reset transistor (4) is turned off in time. Therefore, the great instantaneous current generated when the reset transistor (4) and the evaluating transistor (6) are turned on at the same time is avoided and circuit elements are protected while the power consumption is reduced. The shift register further utilizes an output signal feedback and a dual-gate technique of the input transistors so as to decrease an influence due to a leakage current from the input transistors, which may reduce the power consumption and enhance the stability.

### TECHNICAL FIELD OF THE DISCLOSURE

The present disclosure relates to the technical field of display device, and particularly relates to a shift register, a driving apparatus and a display.

### BACKGROUND

In a usage process of a LCD (Liquid Crystal Display) or OLED (Organic Light-Emitting Diode) display device, scan signals of respective scan lines are controlled by a driving apparatus so as to realize a progressive scanning (or interlaced scanning). For example, in an Active Matrix OLED, the scan lines in the respective rows and data lines in the respective columns intersect and form an active matrix; generally, the progressive scanning is adopted to turn on gate transistors on the respective rows sequentially, so that the voltages on the data lines are transferred to pixel driving transistors and transformed as currents for driving OLEDs.

A driving circuit (that is, the driving apparatus) for the scanning lines is implemented by shift registers, and the shift register may be classed into a dynamic shift register and a static shift register in terms of type. A structure of the dynamic shift register is generally simple and requires less Thin Film Transistors (TFTs), but its power consumption is high and has a limited operation frequency bandwidth; the static shift register requires more TFT elements, but has a large operation bandwidth and a low power consumption. As increasing in a size of a display panel, a row scanning driving circuit is generally realized by a-Si or p-Si transistors and be manufactured on a panel directly, such that interconnections with peripheral driving circuits may be decreased, and the size and the cost are reduced. The row scanning driving circuit which is designed based on the panel does not have high requirement on speed, but needs a compact structure and occupies a small area, therefore it is implemented by the dynamic shift register mostly. Further, the conventional shift register designed by complementary transistors of P type and N type has a complex process implementation and a high cost (typically, it needs 7-9 layers of mask boards), therefore a panel-based design mainly adopts a dynamic circuit being consisted of only N type TFTs or only P type TFTs. In terms of performance of the shift register, factors such as the power consumption, the reliability and the occupied area should be considered synthetically, but the power consumption and the reliability have become more important performance parameter indices as the size of the panel increases gradually.

In the row scanning shift register, an output of the shift register at each stage is connected with an input of the shift register at a next stage, and the shift registers at respective stages are controlled by clock signal lines externally. Generally, the clock control signals are provided specifically from customized external driving ICs, so a degree of difficulty to implement is lower and accuracy is higher if the number of the clocks is less, but the circuit structure of the shift register itself is more complex. On the contrary, the degree of difficulty to implement is higher and the accuracy is lower if the number of the clocks is more, but the circuit structure of the shift register itself is simpler.

In the row scanning shift register, since loads at the output terminals of the shift registers at respective stages are large (typically, tens of PFs), the size of TFTs for driving the output terminals are generally designed as large, such that a reset transistor and an evaluating transistor should be avoided to be turned on at the same time when an evaluation operation or reset operation is perform on the output terminal. If the reset transistor and the evaluating transistor are turned on at the same time, a great instantaneous current may be generated, which may not only increase the power consumption but also cause functions being invalid. Furthermore, if a leakage current generated when a TFT transistor connected with the input terminal is turned off is large, the circuit may be susceptible to the leakage current, such that the evaluating transistor may be turned off accidentally due to a abnormal boosting in a voltage at a gate of the evaluating transistor during the evaluation stage, which may affect the stability in the circuit.

### SUMMARY

### Problem to be Solved

To the above disadvantages, in order to settle a problem of high power consumption and low reliability caused by a great instantaneous current in the shift register in the prior art, the present disclosure provides a shift register capable of preventing a reset transistor and a evaluating transistor from being turned on at the same time by a bootstrapping effect of a capacitor and a pulling-up transistor, which avoids a loss in power consumption and an impact to device caused by the great instantaneous current.

### Technique Solutions

To settle the above problems, the present disclosure adopts the following schemes.

In one aspect, the present disclosure provides a shift register, comprising: an evaluating unit for receiving a second clock signal and outputting an output signal to a signal output terminal under a control of an input signal; a reset controlling unit, a first terminal of which being connected to the evaluating unit and receiving the input signal, a second terminal of which receiving a first clock signal, a third terminal of which receiving a low level signal, for inputting a control signal to a reset unit under controls of the input signal and the first clock signal; the reset unit for receiving a high level signal and resetting the signal output terminal under a control of the control signal input by the reset controlling unit.

In one example, the shift register further comprises a signal inputting unit for receiving the input signal from a signal input terminal and inputting the input signal to the evaluating unit and the reset controlling unit under a control of the first clock signal.

In one example, the shift register further comprises a feedback unit for receiving the output signal from the signal output terminal and inputting a feedback signal to the signal inputting unit.

In one example, the evaluating unit comprises an evaluating transistor and a capacitor, wherein a gate of the evaluating transistor is connected to the first terminal of the reset controlling unit and an output terminal of the signal inputting unit, respectively, a source of the evaluating transistor receives the second clock signal, a drain of the evaluating transistor is connected to the signal output terminal, and the gate and drain of the evaluating transistor are connected to each other via the capacitor.

In one example, the reset controlling unit comprises a pulling-up transistor and a third transistor, a gate of the pulling-up transistor is connected to the gate of the evaluating transistor and the output terminal of the signal inputting unit, respectively, a drain of the pulling-up transistor is connected to the reset unit, a source of the pulling-up transistor receives the first clock signal; a drain of the third transistor receives a digital ground voltage VSS, a gate of the third transistor receives the first clock signal, a source of the third transistor is connected to the drain of the pulling-up transistor and the reset unit.

In one example, the reset unit comprises a reset transistor, a gate of the reset transistor is connected to the drain of the pulling-up transistor, a drain of the reset transistor is connected to the signal output terminal, and a drain of the reset transistor receives an operation voltage VDD.

In one example, the feedback unit comprises: a feedback transistor, a drain and a gate of the feedback transistor are connected to the signal output terminal at the same time, and a source of the feedback transistor is connected to the signal inputting unit.

In one example, the signal inputting unit comprises: a first transistor and a second transistor in a dual-gate structure, a drain of the first transistor and a source of the second transistor are connected to the source of the feedback transistor, a source of the first transistor is connected with the signal input terminal and receives the input signal, a drain of the second transistor is connected with the gate of the evaluating transistor and the gate of the pulling-up transistor, and gates of the first transistor and the second transistor receive the first clock signal simultaneously.

In one example, the first clock signal and the second clock signal are two clock signals both having a duty ratio of 50% but with opposite phases.

In one example, the respective transistors are P-type thin film transistors.

In another aspect, the present disclosure further provides a driving apparatus, wherein the driving apparatus comprises a plurality of above-described shift registers which are connected in cascade, wherein a signal input terminal of the shift register at a first stage receives a start pulse signal STV, and an output terminal of the shift register at each of subsequent stages is connected with an input terminal of the shift register at a next stage, two clock signals received by the shift register at each stage are two clock signals both having a duty ratio of 50% but with opposite phases, and the two clock signals received by the shift registers at two adjacent stages have opposite phases with each other.

In another aspect, the present disclosure further provides a display, wherein the display comprises the driving apparatus above-described therein.

### Beneficial Effects

When the shift register according to the present disclosure evaluates the output terminal, the gate of the pulling-up transistor may be maintained as in the low level by the bootstrapping effect of the capacitor, so that the pulling-up transistor is turned on and charges the gate of the reset transistor rapidly, which renders that the reset transistor is turned off in time. Therefore, the great instantaneous current generated when the reset transistor and the evaluating transistor are turned on at the same time is avoided and circuit elements are protected while the power consumption is reduced.

Additionally, the present disclosure further utilizes the output voltage feedback and the dual-gate technique of the input transistors so as to decrease an influence of a leakage current from the input transistors, which may reduce the power consumption and enhance the stability.

### BRIEF DESCRIPTION OF THE DRAWINGS

FIG. 1 is a block diagram illustrating a structure of the shift register in the present disclosure

FIG. 2 is a schematic diagram illustrating a basic circuit structure of the shift register according to an implementation of the present disclosure;

FIG. 3 is a timing diagram illustrating levels when the shift register shown in FIG. 2 operates;

FIG. 4 is a schematic diagram illustrating a basic circuit structure of a driving apparatus in the present disclosure;

FIG. 5 is a timing diagram illustrating levels when the driving apparatus in the present disclosure operates;

FIG. 6 is a contrast diagram illustrating instantaneous currents, in an evaluating stage and a resetting stage, of the shift register according to the present disclosure vs. a conventional product; and

FIG. 7. is a contrast diagram illustrating voltage changes, at a N1 point, of the shift register according to the present disclosure vs. a conventional product.

### DETAILED DESCRIPTION

Below detailed technical solutions in the embodiments of the present disclosure will be described clearly and completely in connection with the accompanying drawings, and obviously the described embodiments are only a part of embodiments of the present disclosure but not the whole. Based on the embodiments of the present disclosure, other embodiments made by those ordinary skilled in the art without any inventive labors will fall into the scope sought for protection of the present disclosure.

As illustrated in FIG. 1, a shift register of the present disclosure comprises an evaluating unit, a reset controlling unit, a reset unit, a signal inputting unit and a feedback unit.

The evaluating unit is used for receiving a second clock signal and outputting an output signal to a signal output terminal under a control of an input signal. A first terminal of the reset controlling unit is connected to the evaluating unit and receives the input signal, a second terminal of the reset controlling unit receives a first clock signal, a third terminal of the reset controlling unit receives a low level signal, and the reset controlling unit inputs a control signal to a reset unit under controls of the input signal and the first clock signal. The reset unit is used for receiving a high level signal and resetting the signal output terminal under a control of the control signal input by the reset controlling unit.

A signal inputting unit receives the input signal at a signal input terminal IN and inputs the input signal to the evaluating unit and the reset controlling unit under a control of the first clock signal. A feedback unit receives the output signal from the signal output terminal and inputs a feedback signal to the signal inputting unit.

The evaluating unit comprises an evaluating transistor and a capacitor, wherein a gate of the evaluating transistor is connected to the first terminal of the reset controlling unit and an output terminal of the signal inputting unit, respectively, a source of the evaluating transistor receives the second clock signal, a drain of the evaluating transistor is connected to the signal output terminal, and the gate and drain of the evaluating transistor are connected to each other via the capacitor.

The reset controlling unit comprises a pulling-up transistor and a third transistor, a gate of the pulling-up transistor is connected to the gate of the evaluating transistor and the output terminal of the signal inputting unit, respectively, a drain of the pulling-up transistor is connected to the reset unit, a source of the pulling-up transistor receives the first clock signal; a drain of the third transistor receives a digital ground voltage VSS, a gate of the third transistor receives the first clock signal, a source of the third transistor is connected to the drain of the pulling-up transistor and the reset unit.

The reset unit comprises a reset transistor, a gate of the reset transistor is connected to the drain of the pulling-up transistor, a drain of the reset transistor is connected to the signal output terminal, and a drain of the reset transistor receives an operation voltage VDD.

In the shift register according to the present disclosure, the capacitor and the pulling-up transistor are adopted to avoid the reset transistor and the evaluating transistor being turned on at the same time. In particular, as evaluating the output terminal, the gate of the pulling-up transistor may be maintained as in the low level by the bootstrapping effect of the capacitor, so that the pulling-up transistor is turned on and charges the gate of the reset transistor rapidly, which renders the reset transistor is turned off in time. Therefore, the great instantaneous current generated when the reset transistor and the evaluating transistor are turned on at the same time is avoided and the circuit elements are protected while the power consumption is reduced.

In particular, the circuit structure of the shift register according to an implementation of the present disclosure is as shown in FIG. 2. the shift register mainly comprises an evaluating transistor 6, a reset transistor 4 and a pulling-up transistor 5; wherein a gate of the pulling-up transistor 5 is connected with a gate of the evaluating transistor 6, a drain of the pulling-up transistor 5 is connected with a gate of the reset transistor 4, a source of the pulling-up transistor 5 receives a first clock signal CLK, and the gate and a drain of the evaluating transistor 6 are connected with each other via a capacitor. Specifically, the capacitor connected between the gate and drain of the evaluating transistor 6 may be an entity capacitor 8 or a gate-drain parasitic capacitance Cgd existed in the evaluating transistor 6 itself. In an evaluating stage of the shift register, the gate of the pulling-up transistor 5 is maintained as in the low level by a bootstrapping effect of the capacitor connected between the gate and drain of the evaluating transistor 6, so that the pulling-up transistor 5 may be turned on to turn off the reset transistor 4 in time.

Furthermore, in the shift register illustrated in FIG. 2, the signal inputting unit comprises a first transistor 1 and a second transistor 2 in a dual-gate structure, the feedback unit comprises a reset transistor 7, a drain of the first transistor 1 and a source of the second transistor 2 are connected to a source of the feedback transistor 7, a source of the first transistor 1 is connected with a signal input terminal IN of the shift register, a drain of the second transistor 2 is connected with the gate of the evaluating transistor 6 and the gate of the pulling-up transistor 5, the gates of the first transistor 1 and the second transistor 2 receive the first clock signal CLK simultaneously, and a drain and a gate of the feedback transistor 7 are connected with a signal output terminal OUT of the shift register simultaneously. With the above configuration, in the evaluating stage, the shift register of the present disclosure may feedback the output signal at the signal output terminal OUT to the drain of the first transistor 1 and the source of the second transistor 2 by the feedback transistor 7, and reduce a leakage current to the gate of the evaluating transistor 6 from the signal input terminal IN through the second transistor 2. Thus, it may further decrease an influence of the leakage current from the input terminal on the circuit, and prevent a gate voltage of the evaluating transistor 6 from boosting abnormally during the evaluating stage, so that the stability of the circuit may be ensured.

Hereinafter will describe the structure of the shift register according to the present disclosure fully in connection with FIG. 2. In the circuit structure as illustrated in FIG. 2, the shift register according to the present disclosure mainly comprises seven transistors and is controlled by two clocks with opposite polarities. Wherein the first transistor 1 and the second transistor 2 are transistors in the dual-gate structure, the source and drain of the first transistor 1 are connected with the signal input terminal IN and a third circuit node N3, respectively, and the gate of the first transistor 1 is controlled by a first clock CLK; the source and drain of the second transistor 2 are connected with the third circuit node N3 and a first circuit node N1, respectively, and the gate of the second transistor 2 is controlled by the first clock CLK; the source of the evaluating transistor 6 receives a second clock CLKB, the drain of the evaluating transistor 6 is connected with the signal output terminal OUT, the gate of the evaluating transistor 6 is connected to the first circuit node N1; the source of the pulling-up transistor 5 is connected with the first clock CLK, the drain of the pulling-up transistor 5 is connected to a second circuit node N2; the source of the third transistor 3 is connected to the second circuit node N2, the drain of the third transistor 3 receives a digital ground voltage VSS, the gate of the third transistor 3 is controlled by the first clock CLK; the source of the reset transistor 4 receives a power supply voltage VDD, the drain of the reset transistor 4 is connected with the output terminal OUT, the gate of the reset transistor 4 is connected to the second circuit node N2; the drain and source of the feedback transistor 7 are connected with the output terminal OUT and the third circuit node N3, respectively, and the gate of the feedback transistor 7 is connected with the output terminal OUT.

Wherein, the first circuit node N1 is a connection point among the drain of the second transistor 2, the gate of the evaluating transistor 6 and the gate of the pulling-up transistor 5, and the drain of the evaluating transistor 6 is connected with the gate and drain of the feedback transistor 7, the output terminal OUT and the drain of the reset transistor 4; the second circuit node N2 is a connection point among the drain of the pulling-up transistor 5, the drain of the third transistor 3 and the gate of the reset transistor 4; the third circuit node N3 is a connection point among the drain of the first transistor 1, the source of the second transistor 2 and the source of the feedback transistor 7.

The shift register according to the present disclosure may turn on the pulling-up transistor 5 by a fact that the first circuit node N1 is in the low level during the evaluation stage, so that the reset transistor 4 may be turned off in time. In this stage, when size of the evaluating transistor 6 is large enough, a parasitic capacitance Cgd (a gate-drain capacitance) exists in the evaluating transistor 6 itself and may maintain a voltage at the first circuit node N1 for a period of time, thus the voltage at the N1 point would be lower than a low level of the first clock CLK due to a bootstrapping effect of the capacitor and may be about VSS-VDD. Therefore a gate-source voltage of the pulling-up transistor 5 is Vgs=VSS−2 VDD when the first clock CLK is in a high level, which may ensure a large turning-on current and in turn may charge the second circuit node N2 rapidly, so that the reset transistor 4 may be turned off in time. In order to ensure the bootstrapping effect of the capacitor at the N1 point, a capacitor 8 may be connected between the drain and the gate (that is, the N1 point) of the evaluating transistor 6, taking place of the effect of the parasitic capacitance Cgd in the evaluating transistor 6.

Furthermore, during the evaluation stage, the output signal at the signal output terminal OUT is feedback to a middle point N3 between the first transistor 1 and the second transistor 2 in a dual-gate structure by the feedback transistor 7, thus a leakage current in the second transistor 2 is reduced, the voltage at the N1 point is prevented from being charged too high by the input signal, and the influence of the leakage current on the circuit is diminished.

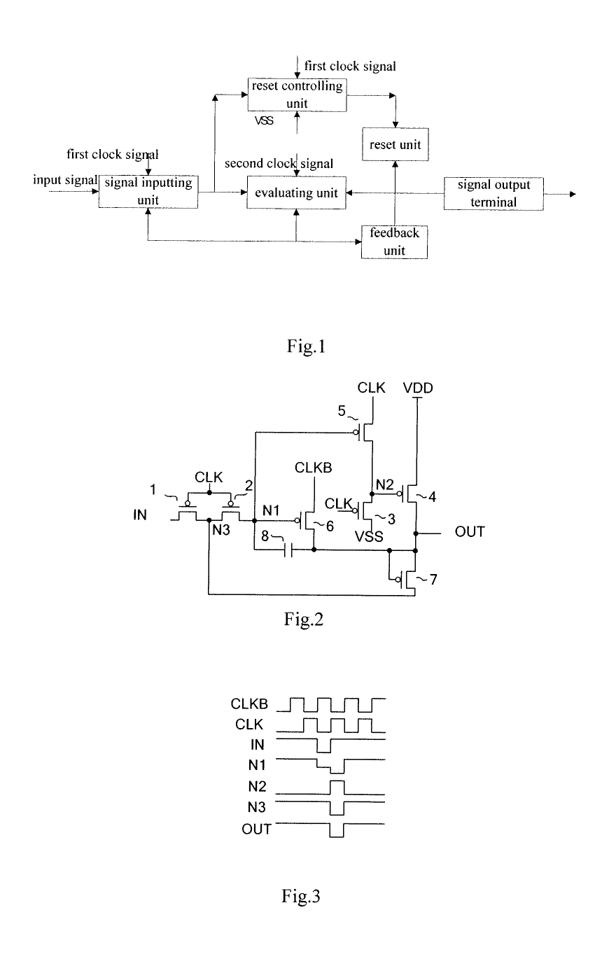

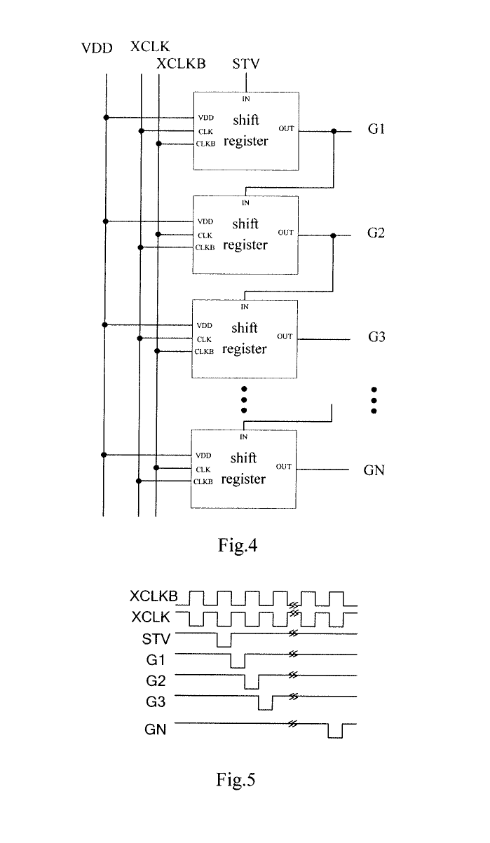

In particular, all of the transistors 1-7 in the shift register according to the present disclosure may be turned on by the low level and turned off by the high level, and the transistors are TFT transistors preferably. In the shift register according to the present disclosure, a timing of levels for respective signals in a complete operation period is as illustrated in FIG. 3.

In an initial state, both of the clock signals CLK and CLKB are in the low level, the signal input terminal IN is in the high level, then the transistors 1, 2, 3, 4 are turned on while the transistors 5, 6, 7 are turned off, an internal node N1 is in the high level, the N2 is in the low level, and the output terminal OUT is in the high level.

When the CLK is in the low level, the CLKB is in the high level and the IN is in the high level, then the transistors 1, 2, 3, 4 are turned on while the transistors 5, 6, 7 are turned off, the internal node N1 is in the high level, the N2 is in the low level, and the output OUT is in the high level.

When the CLK is in the high level, the CLKB is in the low level and the IN is in the high level, then the transistor 4 is turned on while the transistors 1, 2, 3, 5, 6, 7 are turned off, the internal node N1 is in the high level, the N2 is in the low level, and the output OUT is in the high level.

A case wherein the CLK is in the low level, the CLKB is in the high level and the IN is in the low level is a pre-charging stage of the shift register. At this time, the transistors 1, 2 are turned on, so that the low level is transferred to the N1 point and charges the capacitor 8, then the transistor 6 is turned on and the high level of CLKB is transferred to the output terminal OUT, while the transistor 5 is turned on so as to make the level at the N2 point become low and turn on the transistor 4. Meanwhile, the transistor 3 is turned on by the CLK, and in turn the transistor 4 is turned on, so that the high level is transferred to the output terminal and the transistor 7 is turned off at this moment.

A case wherein the CLK is in the high level, the CLKB is in the low level and the IN is in the high level is an evaluating stage of the shift register. At this time, the transistors 1, 2 are turned off, the N1 point floats, and the CLKB becomes low, thus a voltage difference across two terminals of the capacitor 8 stored during the pre-charging stage causes a decrease in the voltage at the node N1, which makes that the transistor 6 is turned on fully and the low level is transferred to the output terminal without any threshold loss. Meanwhile, the transistor 5 is turned on and charges the N2 point to the high level, the transistor 4 is turned off, the transistor 3 is turned off by the high level of the CLK, and a possible direct current path is cut off. At the same time, the transistor 7 is turned on, the low level is transferred to the N3 point, the leakage current in the transistor 2 is decreased, and the N1 is prevented from being charged by the high level input to the input IN through the leakage current in the transistors 1, 2, so that the transistor 6 may be turned on uninfluentially.

Next, a case wherein the CLK is in the low level, the CLKB is in the high level and the IN is in the high level is a resetting stage of the shift register. At this time, the transistors 1, 2 are turned on, the N1 point is charged to the high level, the transistors 5, 6 are turned off, the transistor 3 is turned on so as to discharge the N2 to the low level, the transistor 4 is turned on to reset the output terminal OUT, and meanwhile the transistor 7 is turned off.

Furthermore, a driving apparatus may be configured by connecting the shift registers described above at N stages, wherein N is the number of scan lines in a display device. A structure of the driving apparatus is as illustrated in FIG. 4. In FIG. 4, the driving apparatus is composed by connecting N shift registers, each of the shift register receives two clock signals XCLK, XCLKB both having a duty ratio of 50% but with opposite phases and further receives a high level signal VDD and an input signal. Wherein a signal input terminal IN of the first shift register receives a start pulse signal STV, which is active when being at a low level, and an output terminal OUT of each of the shift registers is connected with the signal input terminal IN of a next shift register, the clock control signals received by two adjacent shift registers have opposite phases with each other, for example, the input terminal of the first clock signal CLK in the shift register at the first stage receives an external clock XCLK, and the input terminal of the second clock signal CLKB therein receives an external clock XCLKB, while the input terminal of the first clock signal CLK in the shift register at the second stage, which is adjacent to the shift register at the first stage, receives the external clock XCLKB, and the input terminal of the second clock signal CLKB therein receives the external clock XCLK.

A timing of levels when the driving apparatus operates is illustrated in FIG. 5, and the two clock signals XCLK, XCLKB provide clock signals levels both having the duty ratio of 50% but with opposite phases continuously. Under the action of the start pulse signal STV, the shift registers at respective stages generate an output level signal sequentially so as to turn on switching transistors on the respective scan lines sequentially, so that voltages on data lines are transferred to driving transistors in pixels on this row and are transformed as currents for driving pixel units to generate image, thus a progressive scanning is finally achieved.

The present disclosure may quicken a charging speed of gate level in the reset transistor by turning on the pulling-up transistor with the low level at the internal node generated from the bootstrapping of the capacitor, eliminate the floating state of the internal nodes in the shift register, such that the internal nodes to be reset rapidly, and achieves technical effects of eliminating the direct current path, reducing the instantaneous current and saving cost. Meanwhile, an output signal feedback and the dual-gate technique of the input transistors are utilized to decrease an influence of a leakage current from the input transistors, thus problems of high power consumption, low reliability and high cost in the conventional design are settled.

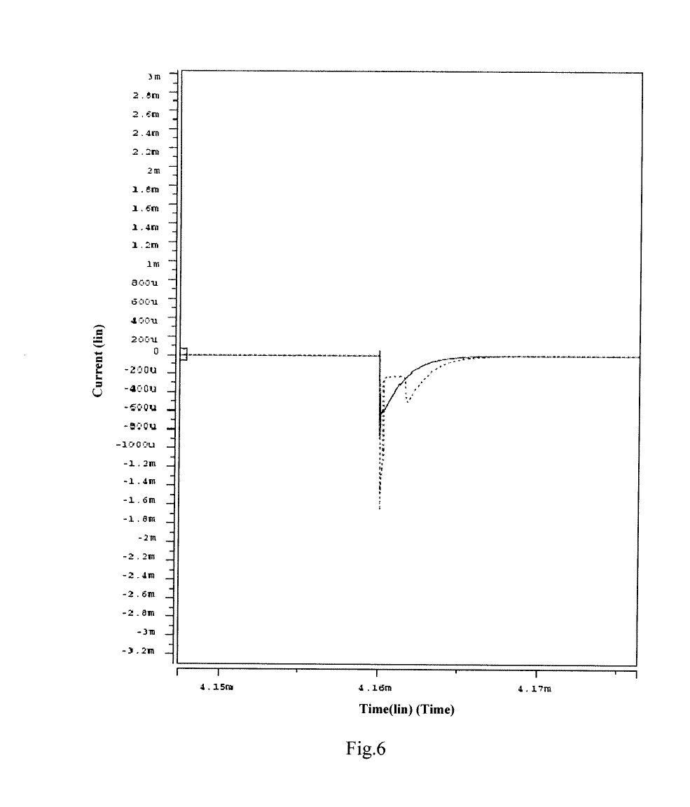

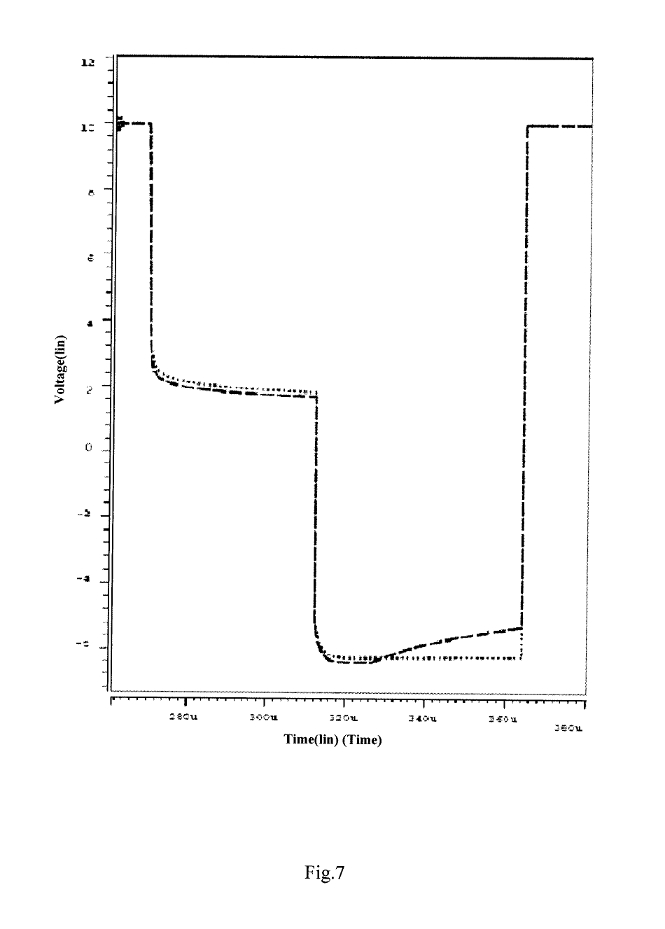

The solution of the present disclosure may reduce dynamic power consumption greatly. As illustrated in FIG. 6, in the evaluating stage and the resetting stage, the instantaneous current (indicated by solid line) is lower than that in the conventional structure (indicated by dotted line). The present disclosure may further restrain a boost in voltage at the N1 point in the evaluating stage and enhance the stability. As illustrated in FIG. 7, the voltage at N1 point (indicated by dotted line) in the solution of the present disclosure is also improved as compared with that in the conventional structure (indicated by dashed line).

Additionally, the solution of the present disclosure may further save area and reduce a design complexity of driving signals, because all of the shift registers share a high level signal VDD and two clock signals XCLK, XCLKB both having the duty ratio of 50% but with opposite phases, thus such solution adopts less clocks and low level signals, has advantage of layout area and does require a complex clock signal generating circuit. The area may be further saved if only the parasitic capacitance Cgd in the evaluating transistor 6 is used.

The thin film transistors in the shift register according to the present disclosure adopt P-type transistors, but obviously may be implemented with N-type thin film transistors after transforming the signal input.

The above are only exemplary embodiments of the disclosed solution, but the scope sought for protection is not limited thereto. Instead, any or all modifications or replacements as would be obvious to those skilled in the art are intended to be included within the scope of the present disclosure. Therefore, the scope of the present disclosure is defined in the appended claims.

1. A shift register, comprising:
an evaluating unit for receiving a second clock signal and outputting an output signal to a signal output terminal under a control of an input signal;
a reset controlling unit, a first terminal of which being connected to the evaluating unit and receiving the input signal, a second terminal of which receiving a first clock signal, a third terminal of which receiving a low level signal, for inputting a control signal to a reset unit under controls of the input signal and the first clock signal;
the reset unit for receiving a high level signal and resetting the signal output terminal under a control of the control signal input by the reset controlling unit.

2. The shift register of claim 1, further comprising a signal inputting unit for receiving the input signal from a signal input terminal and inputting the input signal to the evaluating unit and the reset controlling unit under a control of the first clock signal.

3. The shift register of in claim 2, further comprising a feedback unit for receiving the output signal from the signal output terminal and inputting a feedback signal to the signal inputting unit.

4. The shift register of claim 3, wherein the evaluating unit comprises an evaluating transistor and a capacitor, wherein a gate of the evaluating transistor is connected to the first terminal of the reset controlling unit and an output terminal of the signal inputting unit, respectively, a source of the evaluating transistor receives the second clock signal, a drain of the evaluating transistor is connected to the signal output terminal, and the gate and drain of the evaluating transistor are connected to each other via the capacitor.

5. The shift register of claim 4, wherein the reset controlling unit comprises a pulling-up transistor and a third transistor, a gate of the pulling-up transistor is connected to the gate of the evaluating transistor and the output terminal of the signal inputting unit, respectively, a drain of the pulling-up transistor is connected to the reset unit, a source of the pulling-up transistor receives the first clock signal; a drain of the third transistor receives a digital ground voltage VSS, a gate of the third transistor receives the first clock signal, a source of the third transistor is connected to the drain of the pulling-up transistor and the reset unit.

6. The shift register of claim 5, wherein the reset unit comprises a reset transistor, a gate of the reset transistor is connected to the drain of the pulling-up transistor, a drain of the reset transistor is connected to the signal output terminal, and a drain of the reset transistor receives an operation voltage VDD.

7. The shift register of claim 6, wherein the feedback unit comprises: a feedback transistor, a drain and a gate of the feedback transistor are connected to the signal output terminal at the same time, and a source of the feedback transistor is connected to the signal inputting unit.

8. The shift register of in claim 7, wherein the signal inputting unit comprises: a first transistor and a second transistor in a dual-gate structure, a drain of the first transistor and a source of the second transistor are connected to the source of the feedback transistor, a source of the first transistor is connected with the signal input terminal and receives the input signal, a drain of the second transistor is connected with the gate of the evaluating transistor and the gate of the pulling-up transistor, and gates of the first transistor and the second transistor receive the first clock signal simultaneously.

9. The shift register of claim 1, wherein the first clock signal and the second clock signal are two clock signals both having a duty ratio of 50% but with opposite phases.

10. The shift register of claim 4, wherein the evaluating transistor, the pulling-up transistor, the third transistor, the reset transistor, the feedback transistor, the first transistor and the second transistor are P-type thin film transistors.

11. A driving apparatus comprising a plurality of shift registers which are connected in cascade, wherein a signal input terminal of the shift register at a first stage receives a start pulse signal STV, and an output terminal of the shift register at each of subsequent stages is connected with an input terminal of the shift register at a next stage, two clock signals received by the shift register at each stage are two clock signals both having a duty ratio of 50% but with opposite phases, and the two clock signals received by the shift registers at two adjacent stages have opposite phases with each other.

12. A display comprising the driving apparatus of claim 11.

13. The driving apparatus of claim 11, wherein each of the plurality of shift registers further comprises a signal inputting unit for receiving the input signal from a signal input terminal and inputting the input signal to the evaluating unit and the reset controlling unit under a control of the first clock signal.

14. The driving apparatus of claim 13, wherein each of the plurality of shift registers further comprises a feedback unit for receiving the output signal from the signal output terminal and inputting a feedback signal to the signal inputting unit.

15. The driving apparatus of claim 14, wherein the evaluating unit comprises an evaluating transistor and a capacitor, wherein a gate of the evaluating transistor is connected to the first terminal of the reset controlling unit and an output terminal of the signal inputting unit, respectively, a source of the evaluating transistor receives the second clock signal, a drain of the evaluating transistor is connected to the signal output terminal, and the gate and drain of the evaluating transistor are connected to each other via the capacitor.

16. The driving apparatus of claim 15, wherein the reset controlling unit comprises a pulling-up transistor and a third transistor, a gate of the pulling-up transistor is connected to the gate of the evaluating transistor and the output terminal of the signal inputting unit, respectively, a drain of the pulling-up transistor is connected to the reset unit, a source of the pulling-up transistor receives the first clock signal; a drain of the third transistor receives a digital ground voltage VSS, a gate of the third transistor receives the first clock signal, a source of the third transistor is connected to the drain of the pulling-up transistor and the reset unit.

17. The driving apparatus of claim 16, wherein the reset unit comprises a reset transistor, a gate of the reset transistor is connected to the drain of the pulling-up transistor, a drain of the reset transistor is connected to the signal output terminal, and a drain of the reset transistor receives an operation voltage VDD.

18. The driving apparatus of claim 17, wherein the feedback unit comprises: a feedback transistor, a drain and a gate of the feedback transistor are connected to the signal output terminal at the same time, and a source of the feedback transistor is connected to the signal inputting unit.

19. The driving apparatus of claim 18, wherein the signal inputting unit comprises: a first transistor and a second transistor in a dual-gate structure, a drain of the first transistor and a source of the second transistor are connected to the source of the feedback transistor, a source of the first transistor is connected with the signal input terminal and receives the input signal, a drain of the second transistor is connected with the gate of the evaluating transistor and the gate of the pulling-up transistor, and gates of the first transistor and the second transistor receive the first clock signal simultaneously.

20. The driving apparatus of claim 11, wherein the first clock signal and the second clock signal are two clock signals both having a duty ratio of 50% but with opposite phases.
